(19) United States
(12) Patent Application Publication
(10) Pub. No.: US 2013/0222401 A1
(43) Pub. Date: Aug. 29, 2013

(54) SEMICONDUCTOR PACKAGE, AND INFORMATION PROCESSING APPARATUS AND STORAGE DEVICE INCLUDING THE SEMICONDUCTOR PACKAGES

(71) Applicants: Takayoshi ITO, Yokohama-shi (JP); Koh HASHIMOTO, Yokohama-shi (JP); Yukako TSUTSUMI, Kawasaki-shi (JP); Koji AKITA, Yokohama-shi (JP); Keiju YAMADA, Yokohama-shi (JP)

(72) Inventors: Takayoshi ITO, Yokohama-shi (JP); Koh HASHIMOTO, Yokohama-shi (JP); Yukako TSUTSUMI, Kawasaki-shi (JP); Koji AKITA, Yokohama-shi (JP); Keiju YAMADA, Yokohama-shi (JP)

(73) Assignee: KABUSHIKI KAISHA TOSHIBA, Tokyo (JP)

(21) Appl. No.: 13/600,670

(22) Filed: Aug. 31, 2012

(30) Foreign Application Priority Data
Feb. 28, 2012 (JP) 2012-041830

(51) Int. Cl. H01L 25/16; G06F 13/14

(52) U.S. Cl. 345/519; 257/777; 257/E25.029

(57) ABSTRACT

According to the embodiments, a semiconductor package includes a semiconductor chip, a first conductive layer, a second conductive layer, and a power feeder. The semiconductor chip is provided on a substrate, is sealed with a resin, and contains a transmission/reception circuit. The first conductive layer is grounded and covers a first region on a surface of the resin. The second conductive layer is not grounded and covers a second region on the surface of the resin other than the first region. A power feeder electrically connects the semiconductor chip to the second conductive layer.

### CROSS-REFERENCE TO RELATED APPLICATIONS

This application is based upon and claims the benefit of priority from Japanese Patent Application No. 2012-041830, filed Feb. 28, 2012, the entire contents of which are incorporated herein by reference.

### FIELD

Embodiments described herein relate generally to semiconductor packages.

### BACKGROUND

In the field of semiconductor devices for use in, for example, portable communication apparatuses represented by a mobile phone, there is a demand for suppression of leakage of unnecessary radio waves to the outside of the apparatuses, in order to suppress adverse influence of the waves on the communication characteristics. To satisfy the demand, semiconductor packages having a shielding function have been developed. As the semiconductor packages having the shielding function, those of a structure, in which a shielding layer is provided along the outer surface of a sealing resin layer that seals a semiconductor chip mounted on an interposer substrate, are known.

However, when the semiconductor package is aimed to perform wireless communication with external devices, even the radio waves used for the communication will be shielded, which makes the communication difficult. As a conventional structure developed in view of this, utilizing the fact that the frequency of the unnecessary radio waves is sufficiently lower than that of radio waves used for communication, a structure is known, in which an opening is formed in the shield layer provided on the upper surface of a semiconductor package.

In the conventional structure, however, the distance between the opening for radiating radio waves for communication and a semiconductor chip is short, which reduces the unnecessary radio wave shielding performance. The opening, which is formed in the upper surface of the semiconductor package, is also disadvantageous because lateral communication is hard to perform.

### BRIEF DESCRIPTION OF THE DRAWINGS

FIG. 1 is a perspective view illustrating a semiconductor package according to a first embodiment;

FIGS. 2A, 2B and 2C are schematic views useful in explaining a power feeder incorporated in the semiconductor package of the first embodiment;

FIGS. 3A, 3B, 3C and 3D are perspective views useful in explaining the non-grounded conducting layer of the semiconductor package of the first embodiment;

FIG. 4 is a perspective view illustrating a case where the non-grounded conductive region of the semiconductor package of the first embodiment is of a differential power feed folded dipole form;

FIG. 5 is a view illustrating a radiation pattern of the semiconductor package of the first embodiment;

FIGS. 6A and 6B are schematic views useful in explaining a power feeder of single-phase feeding incorporated in the semiconductor package of the first embodiment;

FIG. 7 is a schematic view useful in explaining a power feeder having two passive elements and incorporated in the semiconductor package of the first embodiment;

FIG. 8 is a schematic view useful in explaining a power feeder incorporated in a semiconductor package according to a second embodiment;

FIG. 9 is a schematic view useful in explaining an information processing apparatus provided with the semiconductor package, according to a third embodiment;

FIG. 10 is a schematic view useful in explaining the information processing apparatus, according to the third embodiment, provided with the semiconductor package and a display unit; and

FIG. 11 is a schematic view useful in explaining a storage device provided with the semiconductor package, according to the third embodiment.

### DETAILED DESCRIPTION

Semiconductor packages, an information processing apparatus and a storage device, according to embodiments, will be described in detail with reference to the accompanying drawings. In the embodiment, like reference numbers denote like elements, and no duplicate explanation will be given. Further, although in the embodiments, a transmission operation is described, a receiving operation can also be performed.

In general, according to the embodiments, a semiconductor package includes a semiconductor chip, a first conductive layer, a second conductive layer, and a power feeder. The semiconductor chip is provided on a substrate, is sealed with a resin, and contains a transmission/reception circuit. The first conductive layer is grounded and covers a first region on a surface of the resin. The second conductive layer is not grounded and covers a second region on the surface of the resin other than the first region. A power feeder electrically connects the semiconductor chip to the second conductive layer.

### First Embodiment

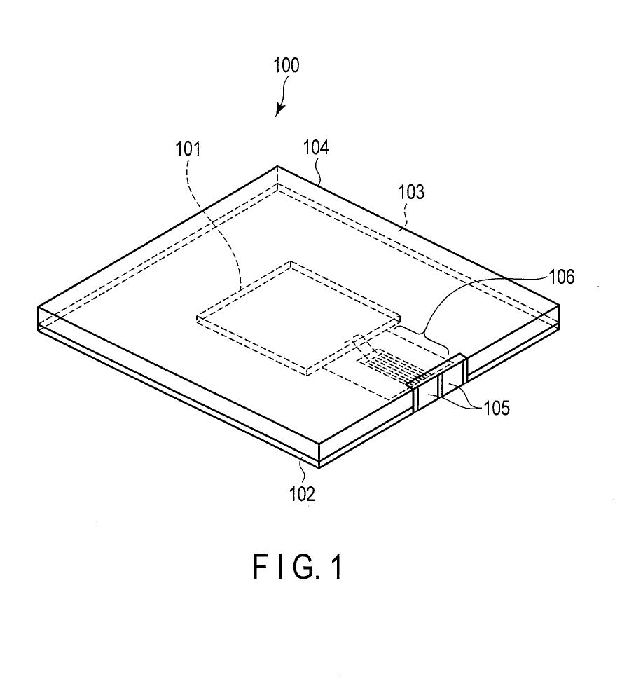

A semiconductor package 100 according to a first embodiment will be described referring to FIG. 1. FIG. 1 is a partially transparent perspective view illustrating the semiconductor package 100 sealed.

In the semiconductor package 100, a semiconductor chip 101 is mounted on a substrate 102 and sealed by a sealing resin 103 as an insulator. The semiconductor chip 101 contains a transmission/reception circuit for transmitting/receiving signals. The sealing resin 103 is covered with a conductive layer 104 formed of a conductor. The conductive layer 104 is electrically connected to a ground layer (not shown) incorporated in the substrate 102, and is therefore grounded. By thus grounding the conductive layer 104, leakage, to the outside of the package, of unnecessary radio waves mainly generated by the semiconductor chip 101 is suppressed.

However, part of the conductive layer 104 is electrically isolated, and is set as a non-grounded conductive layer 105. The non-grounded conductive layer 105 and the semiconductor chip 101 are electrically connected by a power feeder 106, and realize communication with the outside through the non-grounded conductive layer 105.

By thus covering the sealing resin surface of the semiconductor package with a conductive layer, unnecessary radio wave-shielding performance can be imparted. Further, by thus setting part of the conductive layer as a non-grounded region, the part can be used as an antenna.

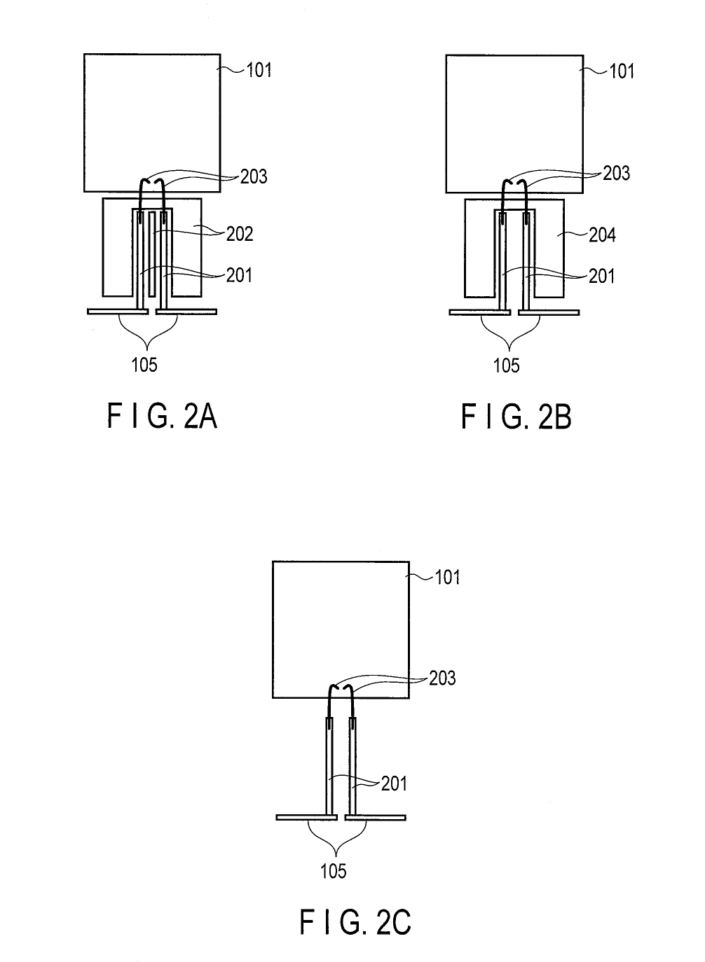

Referring then to FIGS. 2A to 2C, structure examples of the power feeder 106 will be described. In these examples, bonding wires 203 and conductive lines 201 are used to connect the semiconductor chip 101 to the non-grounded conductive layer 105. In FIG. 2A, a coplanar line, in which GND sections 202 are provided outside the conductive lines 201 and between the conductive lines 201, is connected. In FIG. 2B, a coplanar line, in which a GND section 204 is provided only outside the conductive lines 201, is connected. In FIG. 2C, a differential pair line, in which neither of the GRD units 202 and 204 is provided, is connected. Alternatively, a micro-strip line or a strip line may be connected. Yet alternatively, a single-phase line may be employed instead of the differential line. Further, when the semiconductor chip 101 is mounted by a flip chip bonding, a conductive line may be connected through a via without a bonding wire.

By thus connecting the semiconductor chip 101 to an antenna by a power feeding line (such as coplanar line), power loss can be suppressed.

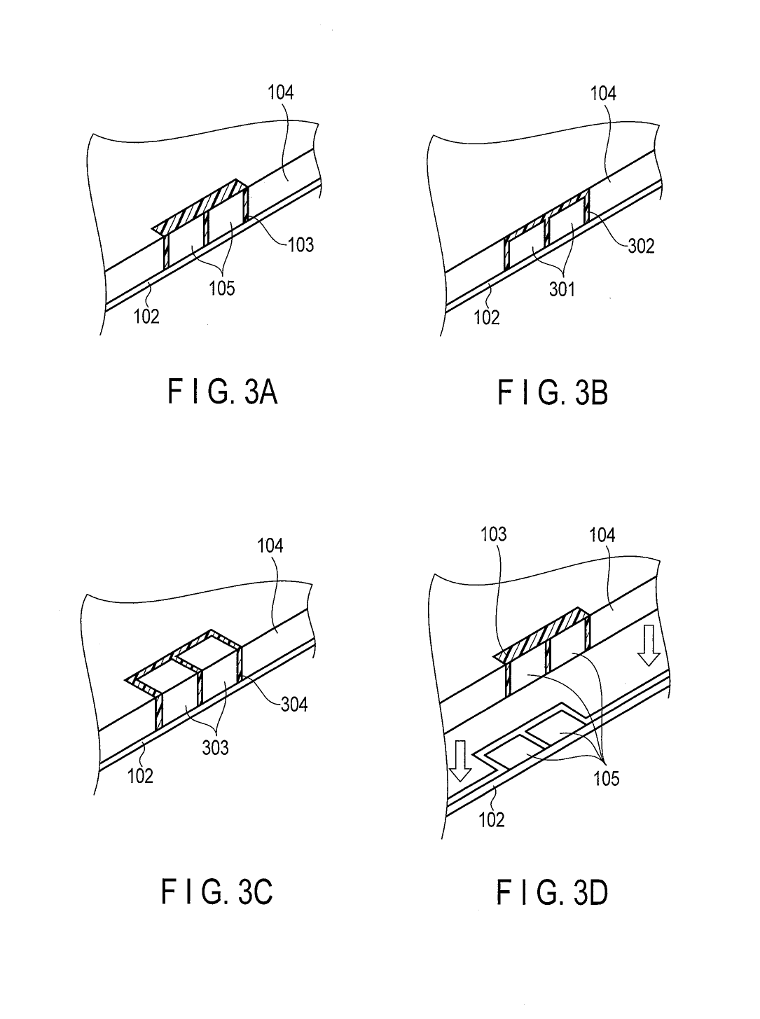

Referring then to FIGS. 3A to 3D, structural examples of the non-grounded conductive layer 105 will be described.

FIG. 3A shows an example where the non-grounded conductive layer 105 is formed along the entire thickness of the sealing resin 103 (i.e., along the thickness obtained by subtracting the thickness of the substrate from that of the semiconductor package). To separate the non-grounded conductive layer 105 from the conductive layer 104, part of the conductive layer 104 on the upper surface of the semiconductor package is removed. The thickness of the sealing resin 103 indicates the length of the resin extending on the substrate perpendicular thereto.

FIG. 3B shows an example where the height of the non-grounded conductive layer 105 is set lower than the thickness of the sealing resin 302. In this structure, it is not necessary to process the upper surface of the semiconductor package. In the examples of FIGS. 3A and 3B, the radiation directivity is lateral, and therefore radio waves can be transmitted laterally with respect to the semiconductor package 100 via the non-grounded conductive layer 105. In the examples of FIGS. 3A and 3B, the non-grounded conductive layer 105 is provided at a lateral portion of the semiconductor package 100. This means that the non-grounded conductive layer 105 is provided on the surface of the semiconductor package 100 perpendicular to the substrate. In other words, the surface of the semiconductor package 100 is perpendicular to a major surface of the substrate.

By thus providing an antenna (i.e., the non-grounded conductive layer 105) on the package lateral surface, lateral communication can be realized. Although the antenna may reduce the shielding performance due to its conductive layer, adverse influence by the reduction of the shielding performance can be suppressed, since the antenna is distant from the noise source (in the semiconductor chip).

FIG. 3C shows an example, where the non-grounded conductive layer 105 is formed on the side and upper surfaces of the semiconductor package. This structure can set the radiation directivity obliquely upward. FIG. 3D is a schematic view, in which the sealing resin 103 and the conductive layer 104 are separated in order to clarify the conductor pattern on the substrate 102. Part of the non-grounded conductive layer 105 is provided on the substrate 102. The non-grounded conductive region on the substrate 102 exists independently of the ambient conductive pattern. This structure can set the radiation directivity obliquely downward. Further, the structure obtained by combining the structures FIGS. 3C and 3D may be employed. Namely, the non-grounded conductive layer 105 may be formed on the upper, lower and lateral surfaces of the semiconductor package.

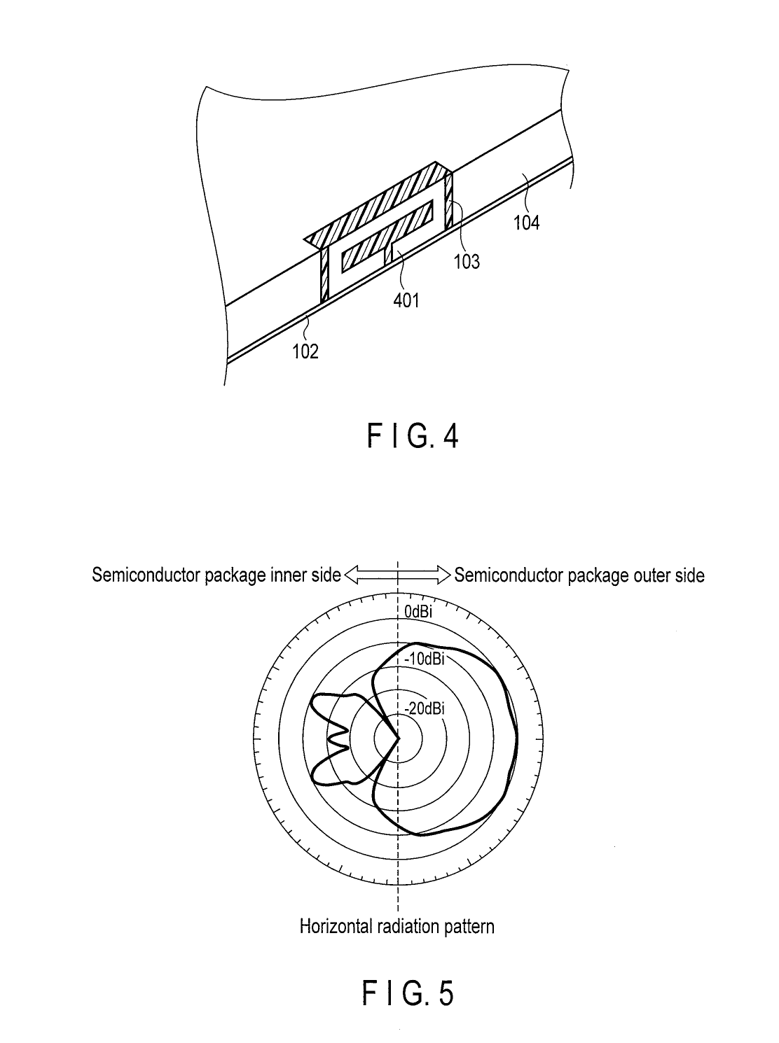

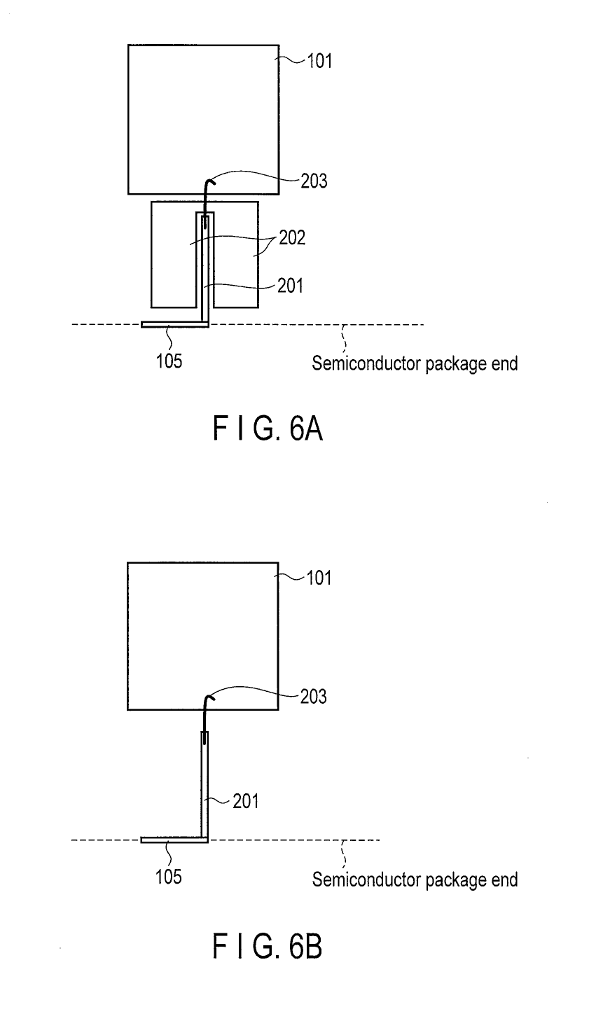

In FIGS. 3A to 3D, the non-grounded conductive layer 105 is of a differential power-feed dipole shape. However, the shape of the non-grounded conductive layer 105 is not limited to this. It is sufficient if the non-grounded conductive layer 105 can emit radio waves for communication. For instance, such a differential power-feed folded dipole shape as shown in FIG. 4 may be employed. In this case, a non-grounded conductive layer 401 is formed in, for example, a “C” shape, and power is fed to the two ends of the C-shaped layer. As will be described later referring to FIG. 6, the power feeding scheme may be a single-phase feeding.

FIG. 5 shows the in-plane radiation pattern of the semiconductor package 100 of FIG. 1. As can be understood from FIG. 5, the main radiation direction exists at the lateral surface of the semiconductor package, in which direction communication can be performed. Although the shielding performance is reduced due to the conductive layer near the non-grounded conductive region, the adverse influence due to reduction of the shielding performance can be minimized because unnecessary radio waves mainly occur at the semiconductor chip and its vicinity.

Referring then to FIG. 6, a description will be given of the case where the power feeding scheme is of a single phase. Both FIGS. 6A and 6B show reverse L-shaped antennas of a single phase.

In FIG. 6A, the power feeding line is a coplanar line in which a GND section 602 is provided outside the conductive line 601. In FIG. 6B, the power feeding line is a micro-strip line without a GND section. By thus employing a single-phase power feeding, the opening area of the conductive layer on the semiconductor package can be made small to thereby enhance the shielding effect.

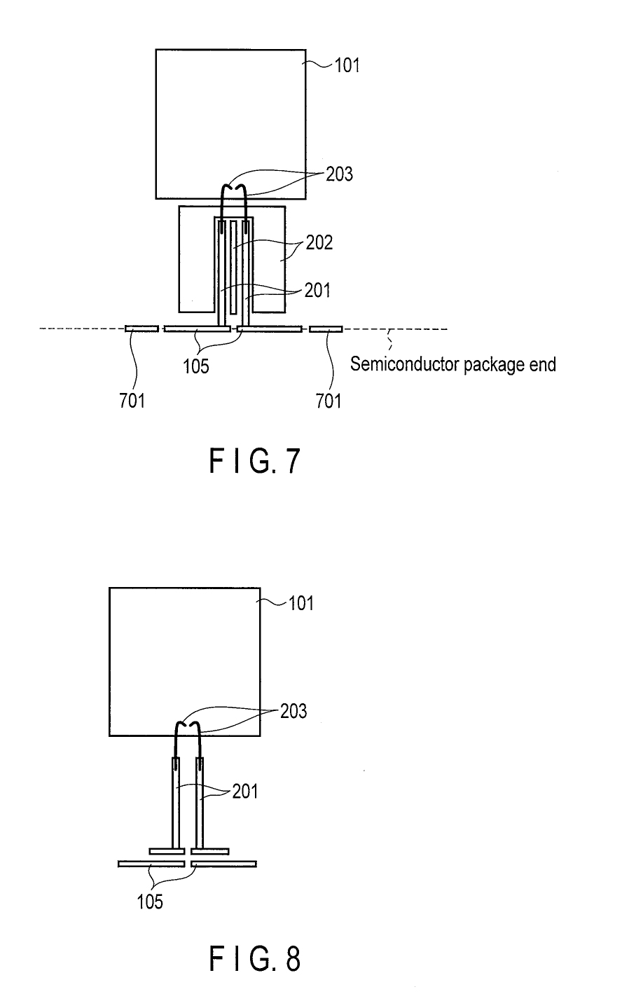

Referring now to FIG. 7, a description will be given of a case where three or more non-grounded conductive layers are employed. FIG. 7 shows a case where four non-grounded conductive layers are provided.

Two of the four non-grounded conductive layers 105 are supplied with power as shown in FIGS. 2A to 2C, while the other two non-grounded conductive layers 701 are not physically coupled to the conductive line 201. If the non-grounded conductive layers 105 and 701 are provided at an end of the package as shown in FIG. 7, the coupling state of the non-grounded conductive layers 105 and 701 varies depending upon frequency. As a result, the non-grounded conductive layers can broaden the operation frequency of the antenna.

In the above-described first embodiment, a shielding function for blocking unnecessary electromagnetic waves can be imparted to the semiconductor package by coating the sealing resin surface of the package with a conductive layer.

Further, an antenna can be provided by making part of the conductive layer as a non-grounded region, with the result that antenna radiation can be improved to thereby enable communication with a wireless apparatus located, for example, laterally.

### Second Embodiment

A semiconductor package according to a second embodiment differs from that of the first embodiment in that in the former, the conductive line and the non-grounded conductive layer are connected by capacitive coupling.

Referring to FIG. 8, the semiconductor package of the second embodiment will be described.

The second embodiment differs from the first embodiment in the shape of the power feeder 106. Specifically, the conductive line 201 is not physically connected to the non-grounded conductive layer 105, but connected thereto via a space. By virtue of this, it is not necessary to keep physical connection between the conductive line 201 and the non-grounded conductive layer 105, which leads to enhancement in the durability of the semiconductor package. Further, by adjusting the shape of the open end of the conductive line 201 and the distance between the line 201 and the non-grounded conductive layer 105, impedance matching can be easily realized.

Although FIG. 8 shows a case where the non-grounded conductive layer 105 is provided on the lateral surface of the semiconductor package as in FIG. 1, the non-grounded conductive layer 105 can also be provided on, for example, the upper surface to realize capacitive coupling between a conductive line (e.g., the conductive line 201) and the non-grounded conductive layer 105 for power feeding. Alternatively, similar power feeding can be realized even by providing the non-grounded conductive layer 105 on the lower surface of the semiconductor package as in the first embodiment.

As described above, the second embodiment, in which the conductive line and the non-grounded conductive layer are connected by capacitive coupling, can provide such advantages, in addition to the advantages of the first embodiment, that impedance matching can be easily matched, and a larger number of options can be presented for the position of the non-grounded conductive layer 105 than in the first embodiment.

### Third Embodiment

A description will now be given of an information processing apparatus and a storage device according to a third embodiment, which are provided with the semiconductor package of the first or second embodiment.

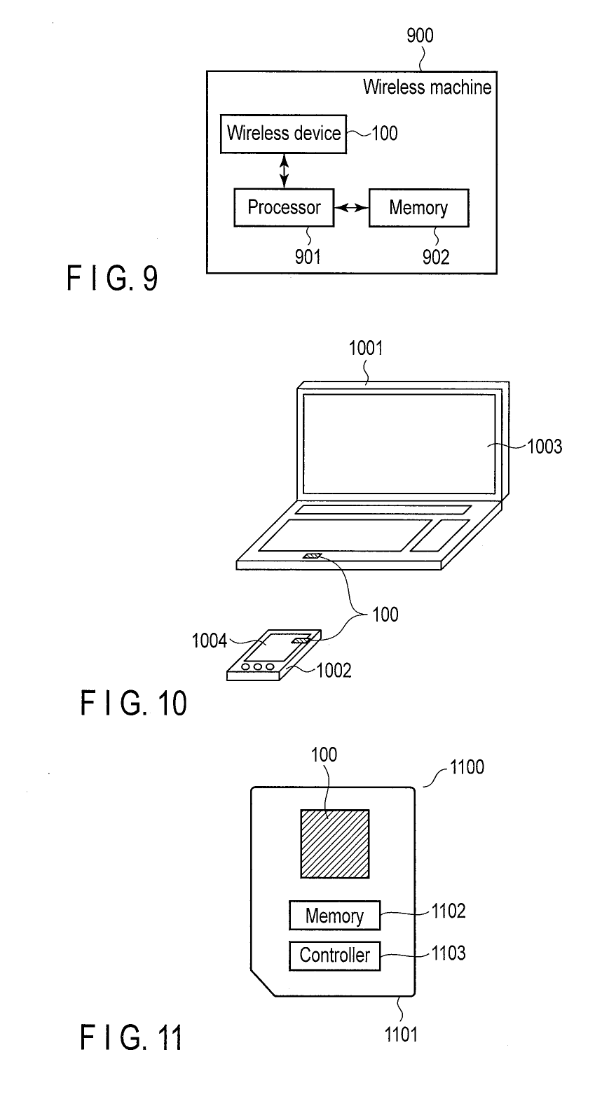

Referring first to FIGS. 9 and 10, the information processing apparatus with the semiconductor package will be described. The information processing apparatus is, for example, a wireless machine 900 as shown in FIG. 9.

As shown in FIG. 9, the wireless machine 900 comprises a wireless device 100, a processor 901 and a memory 902.

The wireless device 100 transmits and receives data from an external device. The wireless device 100 is formed of, for example, the semiconductor package of the first or second embodiment.

The processor (also called a controller) 901 processes data received from and transmitted to the wireless device 100.

The memory 902 stores data received from and transmitted to the processor 901.

Referring then to FIG. 10, examples of the wireless machine with the wireless device 100 will be described.

In this embodiment, the wireless machine examples are a note-type personal computer (note PC) 1001 and a mobile terminal 1002. The note PC 1001 and the mobile terminal 1002 comprise displays 1003 and 1004 for displaying still and moving images. Each of the note PC 1001 and the mobile terminal 1002 also comprises a central processing unit (CPU) (also called a controller), a memory, etc. Each of the note PC 1001 and the mobile terminal 1002 further comprises an internal or external wireless device 100, through which data communication is performed using a frequency of, for example, a millimeter waveband. In the third embodiment, the note PC 1001 and the mobile terminal 1002 may incorporate the semiconductor package 100 of the first or second embodiment.

Further, if the non-grounded conductive layers 105 of the wireless devices incorporated in the note PC 1001 and the mobile terminal 1002 are arranged so that their directions, in which high directivity is obtained, are opposed to each other, exchange of data therebetween can be performed with high efficiency.

Although FIG. 10 shows the note PC 1001 and the mobile terminal 1002, the embodiment is not limited to them, but the wireless devices may be mounted in, for example, a television receiver, a digital camera, a memory card, etc.

Referring then to FIG. 11, a description will be given of a case where the wireless device is installed in a storage device. In the example of FIG. 11, the storage device is a memory card 1100.

As shown in FIG. 11, the memory card 1100 comprises the wireless device 100 and a memory card proper 1101, and can communicate with, for example, a note PC, a mobile terminal, or a digital camera, via the wireless device 100. The memory card proper 1101 comprises a memory 1102 for storing information, and a controller 1103 for controlling the entire device.

In the above-described third embodiment, by installing the semiconductor package in an information processing apparatus or storage device, such as a note PC, a mobile terminal and a memory card, which perform wireless data communication, data transmission and reception can be performed with high efficiency.

In the embodiments described above, a shielding function for blocking unnecessary electromagnetic waves can be imparted to the semiconductor package by coating the sealing resin surface of the package with a conductive layer, and an antenna can be formed by making part of the conductive layer as a non-grounded region, thereby facilitating communication in an arbitrary direction.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiment described herein may be made without departing from the spirit of the invention. The accompanying claims and their equivalents are intended to cover such forms or modifications as would fall within the scope and spirit of the inventions.

What is claimed is:

1. A semiconductor package comprising:
a semiconductor chip provided on a substrate, sealed with a resin, and containing a transmission/reception circuit;
a first conductive layer grounded and covering a first region on a surface of the resin;
a second conductive layer not grounded and covering a second region on the surface of the resin other than the first region; and
a power feeder electrically connecting the semiconductor chip to the second conductive layer.

2. The package according to claim 1, wherein at least part of the second conductive layer is provided on a surface of the semiconductor package, the surface being perpendicular to a major surface of the substrate.

3. The package according to claim 1, wherein the power feeder connects the semiconductor chip to the second conductive layer, and includes a conductive line provided on the substrate.

4. The package according to claim 1, wherein the power feeder is a conductive line connected to the semiconductor chip, provided on the substrate, and including another conductive line connected to the second conductive layer by capacitive coupling.

5. An information processing apparatus comprising:
the semiconductor package according to claim 1;
a controller configured to process data transmitted to and received from the semiconductor package;
a memory configured to store the data; and
a display configured to display an image based on the data.

6. An information processing apparatus comprising:
the semiconductor package according to claim 2;
a controller configured to process data transmitted to and received from the semiconductor package;
a memory configured to store the data; and
a display configured to display an image based on the data.

7. An information processing apparatus comprising:
the semiconductor package according to claim 3;
a controller configured to process data transmitted to and received from the semiconductor package;
a memory configured to store the data; and
a display configured to display an image based on the data.

8. An information processing apparatus comprising:
the semiconductor package according to claim 4;
a controller configured to process data transmitted to and received from the semiconductor package;
a memory configured to store the data; and
a display configured to display an image based on the data.

9. A storage device comprising:
the semiconductor package according to claim 1;
a controller configured to process data transmitted to and received from the semiconductor package; and
a memory configured to store the data.

10. A storage device comprising:
the semiconductor package according to claim 2;
a controller configured to process data transmitted to and received from the semiconductor package; and
a memory configured to store the data.

11. A storage device comprising:
the semiconductor package according to claim 3;
a controller configured to process data transmitted to and received from the semiconductor package; and
a memory configured to store the data.

12. A storage device comprising:
the semiconductor package according to claim 4;
a controller configured to process data transmitted to and received from the semiconductor package; and
a memory configured to store the data.
